(19) United States
(12) Patent Application Publication
(10) Pub. No.: US 2012/0031492 A1
(43) Pub. Date: Feb. 9, 2012

(54) Gallium-Containing Transition Metal Thin Film for CIGS Nucleation

(75) Inventors: Swati Sevvana, Santa Clara, CA (US); Korthan Demirkan, Santa Clara, CA (US); Robert B. Zubeck, Los Altos, CA (US)

(73) Assignee: MiaSole, Santa Clara, CA (US)

(21) Appl. No.: 12/850,190

(22) Filed: Aug. 4, 2010

(51) Int. Cl. H01L 31/032; H01L 31/18

(52) U.S. Cl. 136/262; 438/95; 257/E31.027

(57) ABSTRACT

A solar cell comprises a substrate, a first transition metal layer comprising an alkali element or an alkali compound located over the substrate, a second transition metal layer comprising gallium located over the first transition metal layer, at least one p-type semiconductor absorber layer including a copper indium selenide (CIS) based alloy material located over the second transition metal layer, an n-type semiconductor layer located over the p-type semiconductor absorber layer, and a top electrode located over the n-type semiconductor layer.

### FIELD OF THE INVENTION

The present invention relates generally to the field of photovoltaic devices, and more specifically to forming thin-film solar cells by sputter depositing an alkali-containing transition metal electrode.

### BACKGROUND OF THE INVENTION

Copper indium diselenide (CuInSe₂, or CIS) and its higher band gap variants copper indium gallium diselenide (Cu(In,Ga)Se₂, or CIGS), copper indium aluminum diselenide (Cu(In,Al)Se₂), copper indium gallium aluminum diselenide (Cu(In,Ga,Al)Se₂) and any of these compounds with sulfur replacing some of the selenium represent a group of materials, referred to as copper indium selenide CIS based alloys, have desirable properties for use as the absorber layer in thin-film solar cells (i.e., photovoltaic cells). To function as a solar absorber layer, these materials should be p-type semiconductors. This may be accomplished by establishing a slight deficiency in copper, while maintaining a chalcopyrite crystalline structure. In CIGS, gallium usually replaces 20% to 30% of the normal indium content to raise the band gap; however, there are significant and useful variations outside of this range. If gallium is replaced by aluminum, smaller amounts of aluminum are used to achieve the same band gap.

### SUMMARY OF THE INVENTION

One embodiment of this invention provides a solar cell comprising a substrate, a first transition metal layer located over the substrate, the first transition metal layer further comprising an alkali element or an alkali compound, a second transition metal layer located over the first transition metal layer, the second transition metal layer further comprising gallium, at least one p-type semiconductor absorber layer located over the second transition metal layer, wherein the p-type semiconductor absorber layer includes a copper indium selenide (CIS) based alloy material, an n-type semiconductor layer located over the p-type semiconductor absorber layer, and a top electrode located over the n-type semiconductor layer.

Another embodiment of the invention provides a solar cell comprising a substrate, a first molybdenum layer located over the substrate, the first molybdenum layer further comprising sodium, a second molybdenum layer located over the first molybdenum layer, the second molybdenum layer further comprising gallium, a copper indium gallium selenide (CIGS) p-type semiconductor absorber layer located over the second molybdenum layer, an n-type semiconductor layer located over the p-type semiconductor absorber layer, and a top electrode located over the n-type semiconductor layer.

Another embodiment of the invention provides a method of manufacturing a solar cell comprising providing a substrate, depositing a first transition metal layer over the substrate, the first transition metal layer further comprising an alkali element or an alkali compound, depositing a second transition metal layer over the first transition metal layer, the second transition metal layer further comprising gallium, depositing at least one p-type semiconductor absorber layer over the second transition metal layer, wherein the p-type semiconductor absorber layer includes a copper indium selenide (CIS) based alloy material, depositing an n-type semiconductor layer over the p-type semiconductor absorber layer, and depositing a top electrode over the n-type semiconductor layer. The second transition metal layer permits alkali diffusion from the first transition metal layer into the p-type semiconductor absorber layer during at least one of the steps of depositing the p-type semiconductor absorber layer, depositing the n-type semiconductor layer, or depositing the top electrode.

### BRIEF DESCRIPTION OF THE DRAWINGS

FIG. 1 is a schematic side cross-sectional view of a CIS based solar cell according to one embodiment of the invention.

FIG. 2A shows a highly simplified schematic diagram of a top view of a sputtering apparatus that can be used to forming a first transition metal layer such as an alkali-containing transition metal layer, for example, a sodium-containing molybdenum film.

FIG. 2B shows a highly simplified schematic diagram of a top view of a sputtering apparatus that can be used to forming a second transition metal layer such as an gallium-containing transition metal layer, for example, a gallium-containing molybdenum film.

FIG. 3 shows a highly simplified schematic diagram of a top view of a modular sputtering apparatus that can be used to manufacture the solar cell depicted in FIG. 1.

FIG. 4 illustrates schematically the use of three sets of dual magnetrons to increase the deposition rate and grade the composition of the CIS layer to vary its band gap.

### DESCRIPTION OF THE PREFERRED EMBODIMENTS

As grown CIS films are intrinsically p-type. However, it was found that a small amount of sodium dopants in CIS films increases the p-type conductivity of the CIGS film and the open circuit voltage, and in turn, improves the efficiency of the solar cell. For example, Ramanathan (Ramanathan et al., Prog. Photovolt. Res. Appl. 11 (2003) 225, incorporated herein by reference in its entirety) teaches that a solar cell, having an efficiency as high as 19.5%, may be obtained by using a soda-lime glass substrate in combination with depositing a CIS film under a high growth temperature. This method significantly improves the efficiency of a traditional solar cell by diffusing sodium from the glass substrate into the CIS film. However, it is difficult to control the amount of the sodium provided to the CIS film and the speed of the sodium diffusion from a glass substrate. Furthermore, unlike glass substrates, other substrates, such as metal and plastic substrates, do not provide such a readily available supply of sodium.

Related studies show that CIGS having a high gallium content has a higher bandgap and an improved adhesion to the Mo bottom electrode (see Dullweber et al., Thin Solid Films 387 (2001) 11-13; Lundberg et al., Thin Solid Films 480-481 (2005) 520-525); and Topic et al., J. Appl. Phys. 79 (1996) 8537-8540). It is also suggested that a gallium gradient at the Mo/CIGS interface can yield to better collection efficiency for long wavelength excitations, indicating passivation of the Mo/CIGS contact. However, in order to obtain a CIGS layer having a higher gallium content and the Mo/CIGS interface than at the top of the CIGS layer, and additional CIG target with higher gallium composition is required, which is not desired in manufacturing of the solar cells.

One embodiment of this invention provides a transition metal layer containing gallium between the CIGS layer and the back electrode in a CIGS type solar cell. Specifically, in one embodiment of this invention, a solar cell may comprise a substrate, a first transition metal layer comprising an alkali element or an alkali compound located over the substrate, a second transition metal layer comprising gallium located over the first transition metal layer, at least one p-type semiconductor absorber layer (e.g., a CIGS layer) located over the second transition metal layer, an n-type semiconductor layer located over the p-type semiconductor absorber layer, and a top electrode located over the n-type semiconductor layer. One advantage of the above described configuration is that high gallium content at the bottom electrode/CIGS layer interface results in good CIGS layer adhesion. In other words, disposing the second transition metal layer comprising gallium (e.g., a gallium containing molybdenum layer) between the CIGS layer and the first transition metal layer (e.g., a sodium containing molybdenum layer) improves the adhesion between the CIGS and the first transition metal layer. Another advantage is that the high gallium content may also create a back field, which reduces recombination and improves open circuit voltage and short circuit current.

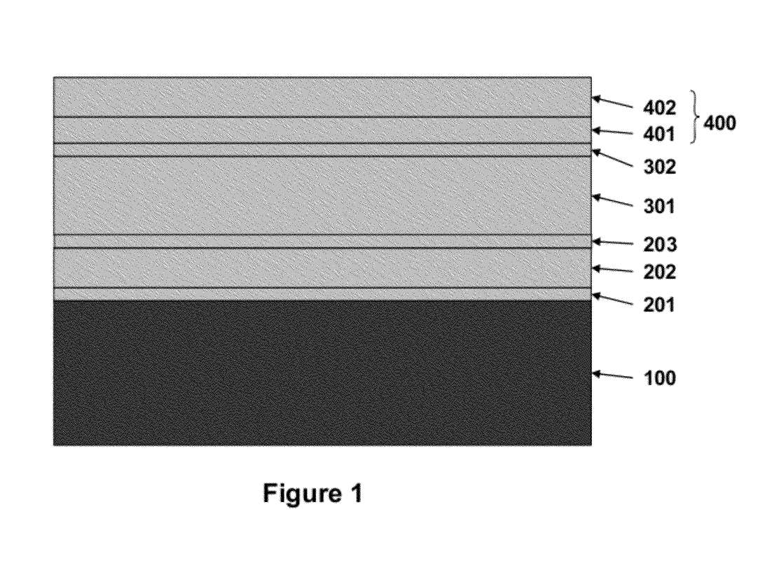

As illustrated in FIG. 1, one embodiment of the invention provides a solar cell which contains a substrate 100 and a first transition metal layer 202 containing at least an alkali element or an alkali compound over the substrate 100, and a second transition metal layer 203 comprising gallium over the first transition metal layer 202. The solar cell may further comprise an optional alkali diffusion barrier layer 201 located between the substrate 100 and the first transition metal layer 202. Additional adhesion layer (not shown) may be further disposed between the first transition metal layer 202 and the substrate 100, for example between the optional alkali diffusion barrier layer 201 and the substrate 100. In some embodiments, the adhesion layer comprises at least 90 atomic percent chromium, such as 90 to 100 atomic percent Cr.

The transition metal of the first transition metal layer 202 may be any suitable transition metal, including but not limited to Mo, W, Ta, V, Ti, Nb, and Zr. The alkali element or alkali compound may comprise one or more of Li, Na, and K. The first transition metal layer 202 may have a thickness of 100 to 500 nm, for example 200 to 400 nm, such as around 300 nm.

In some embodiments, the first transition metal layer 202 contains an alkali element or an alkali compound but is substantially free of the lattice distortion element or compound. Alternatively, the first transition metal layer 202 may further comprise a lattice distortion element or a lattice distortion compound. The lattice distortion element or the lattice distortion compound may be any suitable element or compound, for example, oxygen, nitrogen, sulfur, selenium, an oxide, a nitride, a sulfide, a selenide, an organometallic compound (e.g. a metallocene, a metal carbonyl such as tungsten pentacyonyl and tungsten hexacarbonyl, and the like), or combinations thereof. In some embodiments, when the transition metal is molybdenum, the latter distortion element may be oxygen, forming the first transition metal layer 202 of body centered cubic Mo lattice distorted by face centered cubic oxide compositions, such as MoO₂ and MoO₃. For example, in a non-limiting example, the first transition metal layer 202 may comprise molybdenum containing oxygen and sodium, such as a transition metal layer comprising at least 59 atomic percent molybdenum, 5 to 40 atomic percent oxygen and 0.01 to 1.5 atomic percent sodium. In some embodiments, the first transition metal layer 202 may further contain elements other than molybdenum, oxygen and sodium, such as other materials that are diffused into this layer during deposition, such as indium, copper, selenium and/or barrier layer metals.

The second transition metal layer 203 comprises gallium. The transition metal of the second transition metal layer 203 may be same or different from the transition metal of the first transition metal layer 202. Preferably, they are the same. Similarly, any suitable transition metal, including but not limited to Mo, W, Ta, V, Ti, Nb, and Zr, may be used as the transition metal of the second transition metal layer 203. For example, in some embodiments, the second transition metal layer 203 comprises molybdenum and gallium. The second transition metal layer 203 may have a thickness of about 20 to 80 nm, such as 30 to 70 nm.

In some embodiments, the second transition metal layer 203 further comprises at least one of copper, indium, aluminum, or combinations thereof. For example, in a non-limiting example, the second transition metal layer 203 may contain molybdenum, gallium and copper. For example, a transition metal layer 203 may contain 50 to 90 atomic percent molybdenum, 10 to 50 atomic percent gallium and 0 to 10 atomic percent of at least one of copper, indium and aluminum. For example, layer 203 may contain no copper, no indium, and no aluminum. Alternatively, layer 203 may contain 1-10 atomic percent of Cu, or 1-10 atomic percent In, or 1-10 atomic percent Al, or 1-10 atomic percent of a combination of any two of or all three of Cu, In and Al.

The gallium content in the second transition metal layer 203 may be graded or uniformly distributed. For example, in some embodiments, the second transition metal layer 203 may comprise multiple sub-layers, for example 1 to 20 sub-layers such as 1 to 10 sub-layers. Each sub-layer has a different gallium concentration, resulting in a graded gallium concentration profile within the second transition metal layer 203. Preferably, the higher gallium concentration is located on the upper portion of layer 203 which is located adjacent to the CIGS layer 301.

The optional alkali diffusion barrier layer 201 may comprise any suitable materials. For example, they may be independently selected from a group consisting of Mo, W, Ta, V, Ti, Nb, Zr, Cr, TiN, ZrN, TaN, VN, or combinations thereof. In some embodiments, the alkali diffusion barrier layer 201 comprises at least 90 atomic percent molybdenum. The alkali diffusion barrier layer may have a thickness of about 100 to 400 nm such as 100 to 200 nm.

Preferably, the alkali diffusion barrier layer 201 has a greater thickness and a higher density than the second transition metal layer 203. The higher density and greater thickness of the alkali diffusion barrier layer 201 substantially reduces/prevents alkali diffusion from the first transition metal layer 202 into the substrate 100. On the other hand, the second transition metal layer 203 has a higher porosity than the alkali diffusion barrier layer 201 and permits alkali diffusion from the first transition metal layer 202 into the p-type semiconductor absorber layer 301. In these embodiments, alkali may diffuse from the first transition metal layer 202, through the lower density second transition metal layer 203, into the at least one p-type semiconductor absorber layer 301 during and/or after the step of depositing the at least one p-type semiconductor absorber layer 301.

In preferred embodiments, the p-type semiconductor absorber layer 301 located over the second transition metal layer 203 may comprise a CIS based alloy material selected from copper indium selenide, copper indium gallium selenide, copper indium aluminum selenide, or combinations thereof. Layer 301 may have a stoichiometric composition having a Group I to Group III to Group VI atomic ratio of about 1:1:2, or a non-stoichiometric composition having an atomic ratio of other than about 1:1:2. Preferably, layer 301 is slightly copper deficient and has a slightly less than one copper atom for each one of Group III atom and each two of Group VI atoms. The step of depositing the at least one p-type semiconductor absorber layer may comprise reactively AC sputtering the semiconductor absorber layer from at least two electrically conductive targets in a sputtering atmosphere that comprises argon gas and a selenium containing gas (e.g. selenium vapor or hydrogen selenide). For example, each of the at least two electrically conductive targets comprises copper, indium and gallium; and the CIS based alloy material comprises copper indium gallium diselenide.

Gallium may diffuse from the second transition metal layer 203 to the CIS based alloy (e.g., CIGS) layer 301. In some embodiments, the p-type semiconductor absorber layer 301 may comprise a first portion adjacent to the second transition metal layer 203 which contains more gallium then a second portion distant from the second transition metal layer 203. Furthermore, sodium impurities may diffuse from the first transition metal layer 202 to the CIS based alloy layer 301 through the second transition metal layer 203. In one embodiment, the p-type semiconductor absorber layer 301 may comprise 0.03 to 1.5 atomic percent sodium diffused from the first transition metal layer 202 through the second transition metal layer 203. In one embodiment, the sodium impurities may concentrate at the grain boundaries of CIS based alloy, and may have a concentration as high as 10²¹ to 10²² atoms/cm³.

An n-type semiconductor layer 302 may then be deposited over the p-type semiconductor absorber layer 301. The n-type semiconductor layer 302 may comprise any suitable n-type semiconductor materials, for example, but not limited to ZnS, ZnSe or CdS.

A transparent top electrode 400, is further deposited over the n-type semiconductor layer 302. The transparent top electrode 400 may comprise multiple transparent conductive layers, for example, but not limited to, an Indium Tin Oxide (ITO) layer 402 located over an optional intrinsic Zinc Oxide or a resistive Aluminum Zinc Oxide (AZO, also referred to as RAZO) layer 401. Of course, the transparent top electrode 400 may comprise any other suitable materials, for example, doped ZnO or SnO.

Optionally, one or more antireflection (AR) films (not shown) may be deposited over the transparent top electrode 400, to optimize the light absorption in the cell, and/or current collection grid lines may be deposited over the top conducting oxide.

A solar cell described above may be fabricated by any suitable methods. In one embodiments, a method of manufacturing such a solar cell comprising providing the substrate 100, depositing the first transition metal layer 202 comprising an alkali element or an alkali compound over the substrate 100, depositing the second transition metal layer 203 comprising gallium over the first transition metal layer 202, depositing the at least one p-type semiconductor absorber layer 301 containing a copper indium selenide (CIS) based alloy material over the second transition metal layer 203, depositing the n-type semiconductor layer 302 over the p-type semiconductor absorber layer 301, and depositing the top electrode 400 over the n-type semiconductor layer 302. Optionally, an adhesion layer may be deposited over the substrate 100 followed by depositing the alkali diffusion barrier layer 201 prior to depositing layer 202. Preferably, the second transition metal layer 203 permits alkali diffusion from the first transition metal layer 202 into the p-type semiconductor absorber layer 301 during at least one of the steps of depositing the p-type semiconductor absorber layer 301, depositing the n-type semiconductor layer 302, or depositing the top electrode 400.

Any desirable method, for example but not limited to MBE, CVD, evaporation, plating, etc., may be used for depositing the above described layers. For example, the layers may be deposited over the substrate by sputtering. In some embodiments, one or more sputtering steps may be reactive sputtering.

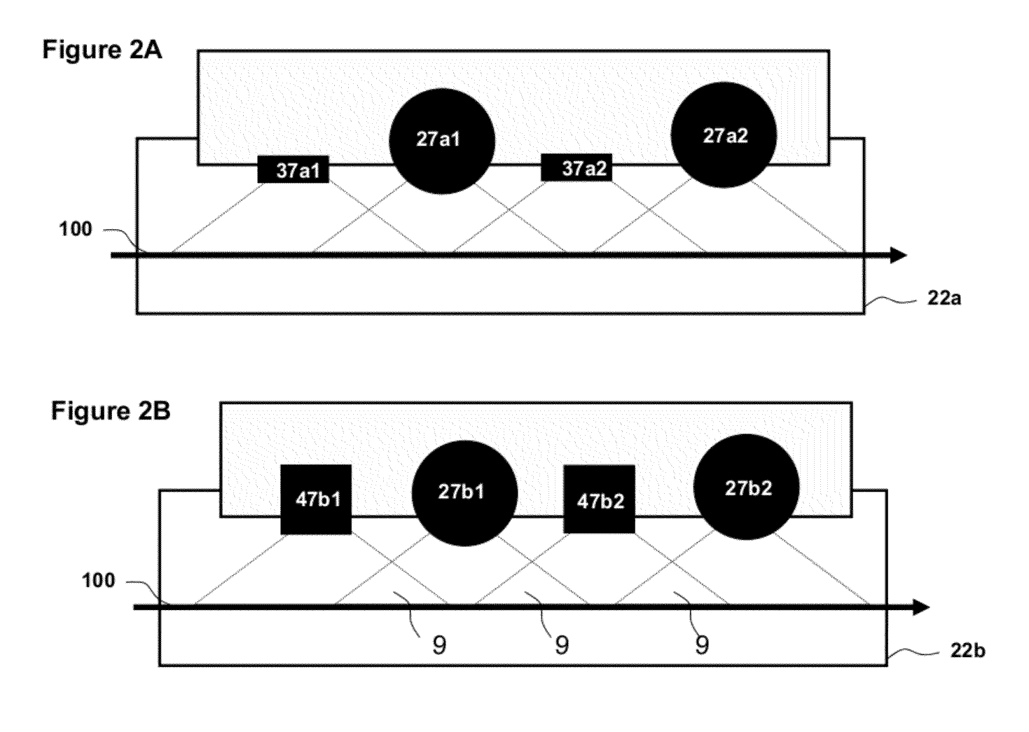

In a non-limiting example, a sputtering apparatus illustrated in FIG. 2A may be used for depositing the first transition metal layer (not shown in FIG. 2A, and referred to as layer 202 in FIG. 1) over a substrate 100. Targets comprising an alkali-containing material (e.g., targets 37a1 and 37a2) and targets comprising a transition metal (e.g., 27a1 and 27a2) are located in a sputtering process module 22a, such as a vacuum chamber. In a non-limiting example, the transition metal targets 27a1 and 27a2 are rotating Mo cylinders and are powered by DC power sources 7, and the alkali-containing targets 37a1 and 37a2 are planar NaF targets and are powered by RF generators through matching networks. The target types alternate and end with a transition metal target, for example target 27a2 as shown in FIG. 2A.

In some embodiments, the step of depositing the first transition metal layer 202 may be conducted in an oxygen and/or nitrogen rich environment, and may comprise DC sputtering the transition metal from the first target and pulsed DC sputtering, AC sputtering, or RF sputtering the alkali compound from the second target. Any suitable variations of the sputtering methods may be used. For example, for electrically insulating second target materials, AC sputtering refers to any variation of AC sputtering methods that may be used to for insulating target sputtering, such as medium frequency AC sputtering or AC pairs sputtering. In one embodiment, the step of depositing the first transition metal layer may comprise DC sputtering a first target comprising a transition metal, such as molybdenum, and pulsed DC sputtering, AC sputtering, or RF sputtering a second target comprising alkali-containing material, such as a sodium-containing material, in an oxygen rich sputtering environment. The sodium-containing material may comprise any material containing sodium, for example alloys or compounds of sodium with one or more of selenium, sulfur, oxygen, nitrogen or barrier metal (such as molybdenum, tungsten, tantalum, vanadium, titanium, niobium or zirconium), such as sodium fluoride, sodium molybdate, sodium fluoride, sodium selenide, sodium hydroxide, sodium oxide, sodium sulfate, sodium tungstate, sodium selenate, sodium selenite, sodium sulfide, sodium sulfite, sodium titanate, sodium metavanadate, sodium orthovanadate, or combinations thereof. Alloys or compounds of lithium and/or potassium may be also used, for example but not limited to alloys or compounds of lithium or potassium with one or more of selenium, sulfur, oxygen, nitrogen, molybdenum, tungsten, tantalum, vanadium, titanium, niobium or zirconium. The transition metal target may comprise a pure metal target, a metal alloy target, a metal oxide target (such as a molybdenum oxide target), etc. If desired, a single sodium containing molybdenum target may be used instead of separate molybdenum and sodium containing targets. The single sodium containing molybdenum target may comprise 0.01 to 5 atomic percent sodium, optionally 5 to 40 atomic percent oxygen, and the rest (e.g., at least 59 atomic percent) molybdenum.

The substrate 100 may be a foil web, for example, a metal web substrate, a polymer web substrate, or a polymer coated metal web substrate, and may be continuously passing through the sputtering module 22a during the sputtering process, following the direction of the imaginary arrow along the web 100. Any suitable materials may be used for the foil web. For example, metal (e.g., stainless steel, aluminum, or titanium) or thermally stable polymers (e.g., polyimide or the like) may be used. The foil web 100 may move at a constant or variable rate to enhance intermixing.

The second transition metal layer 203 comprising gallium may then be deposited over the first transition metal layer 202. The transition metal of the second transition metal layer 203 may be same or different from the transition metal of the first transition metal layer 202. Similarly, any suitable transition metal, for example but not limited to Mo, W, Ta, V, Ti, Nb, and Zr, may be used as the transition metal of the second transition metal layer 203. For example, in some embodiments, the second transition metal layer 203 comprises molybdenum containing gallium. For example, in a non-limiting example, the second transition metal layer comprises 50 to 90 atomic percent molybdenum and 10 to 50 atomic percent gallium.

In some other embodiments, the second transition metal layer 203 further comprises at least one of copper, indium, aluminum, or combinations thereof. For example, in a non-limiting example, the second transition metal layer may be a transition metal layer containing molybdenum, gallium and copper, for example a transition metal layer containing 50 to 90 atomic percent molybdenum, 10 to 50 atomic percent gallium and 0 to 10 atomic percent copper, indium and/or aluminum.

The step of depositing the second transition metal layer 203 may comprise sputtering the second transition metal layer 203 from a target comprising a molybdenum gallium copper alloy, a molybdenum gallium indium alloy, a molybdenum gallium aluminum alloy or a molybdenum gallium alloy having about the same composition ranges as those described for layer 203 above. Alternatively, the step of depositing the second transition metal layer 203 may comprise sputtering the second transition metal layer 203 from one or more pairs of targets which include a first target 27b1 comprising molybdenum and a second target 47b1 comprising a gallium alloy (e.g., copper gallium, aluminum gallium or copper aluminum gallium) or a gallium target (e.g., a gallium reservoir in which gallium is liquid at the sputtering temperature). The first target comprising molybdenum and the second target comprising a gallium alloy, such as copper gallium, may be located in the same vacuum chamber 22b of a magnetron sputtering system, as shown in FIG. 2B, similar to that used for depositing the first transition metal layer 202 shown in FIG. 2A. The distance between the adjacent targets is small enough such that a sufficient overlap 9 may exist between the alternating molybdenum containing fluxes and copper gallium alloy containing fluxes and thus enhance the intermixing of the molybdenum and the copper gallium material during depositing the second transition metal layer 203 containing gallium and copper. If desired, there may be several gallium containing targets (e.g., targets 47b1 and 47b2) and several transition metal targets, such as molybdenum targets (e.g., 27b1 and 27b2) located in a sputtering process module 22b, such as a vacuum chamber. In a non-limiting example, the transition metal targets 27b1 and 27b2 are rotating Mo cylinders that are powered by DC power sources, and the copper gallium alloy targets 47b1 and 47b2 are either rotating cylinders that are powered by DC power sources or planar targets that are powered by RF generators through matching networks. The copper gallium target's copper content should be equal or greater than half the atomic content of gallium (e.g., a Cu:Ga atomic ratio of at least 1:2, such as 1:2 to 2:1) to achieve a desired Cu:Ga ratio in the sputtered layer 203 and to preferably maintain the alloy target in the solid rather than liquid state at the sputtering temperature. Preferably, the target 47b1, 47b2 contains at least 33 atomic percent copper such that the target remains solid at 300° C. or above.

Preferably, the gallium content of the second transition metal layer 203 may diffuse from the second transition metal layer 203 into the p-type semiconductor absorber layer 301 during at least one of the steps of depositing the at least one p-type semiconductor absorber layer 301, depositing the n-type semiconductor layer 302, depositing the top electrode 400, and an optional post-deposition annealing process. Similarly, the alkali dopant (e.g., sodium dopant) of the first transition metal layer 202 may diffuse from the first transition metal layer 202 into the p-type semiconductor absorber layer 301 through the second transition metal layer 203 during at least one of the steps of depositing the at least one p-type semiconductor absorber layer 301, depositing the n-type semiconductor layer 302, depositing the top electrode 400, and an optional post-deposition annealing process, such that the p-type semiconductor absorber layer 301 comprises copper indium gallium selenide containing 0.03 to 1.5 atomic percent alkali dopant (e.g., sodium dopant) diffused from the first transition metal layer 202. The amount of sodium diffused into the at least one p-type semiconductor absorber layer 301 may be tuned by controlling the thickness and/or density of the second transition metal layer 203, which in turn may be tuned by controlling the sputtering rate and/or sputtering parameters such as sputtering power and pressure in the sputtering chamber.

Optionally, an alkali diffusion barrier layer 201 may be deposited over the substrate 100 prior to the step of depositing the first transition metal layer 202. The alkali diffusion barrier layer 201 comprises at least one of Mo, W, Ta, V, Ti, Nb, or Zr, and may have a thickness of around 100 to 400 nm. In some embodiments, the step of sputtering the alkali diffusion barrier layer 201 occurs at a lower pressure than the step of sputtering the second transition metal layer 203. The alkali diffusion barrier layer 201 substantially prevents alkali dopants diffusion from the first transition metal layer 202 into the substrate 100.

In some embodiments, the steps of depositing the alkali diffusion barrier layer 201, depositing the first transition metal layer 202 and depositing the second transition metal layer 203 comprises sputtering the alkali diffusion barrier layer 201, sputtering the first transition metal layer 202, and sputtering the second transition metal layer 203 in the same sputtering apparatus.

More preferably, the steps of depositing the alkali diffusion barrier layer 201, depositing the first transition metal layer 202 and depositing the second transition metal layer 203, depositing the at least one p-type semiconductor absorber layer 301, depositing the n-type semiconductor layer 302, and depositing the top electrode 400 comprise sputtering the alkali diffusion barrier layer 201, the first transition metal layer 202, the second transition metal layer 203, the p-type absorber layer 301, the n-type semiconductor layer 302 and one or more conductive films of the top electrode 400 over the substrate 100 (preferably a web substrate in this embodiment) in corresponding process modules of a plurality of independently isolated, connected process modules without breaking vacuum, while passing the web substrate 100 from an input module to an output module through the plurality of independently isolated, connected process modules such that the web substrate continuously extends from the input module to the output module while passing through the plurality of the independently isolated, connected process modules. Each of the process modules may include one or more sputtering targets for sputtering material over the web substrate 100.

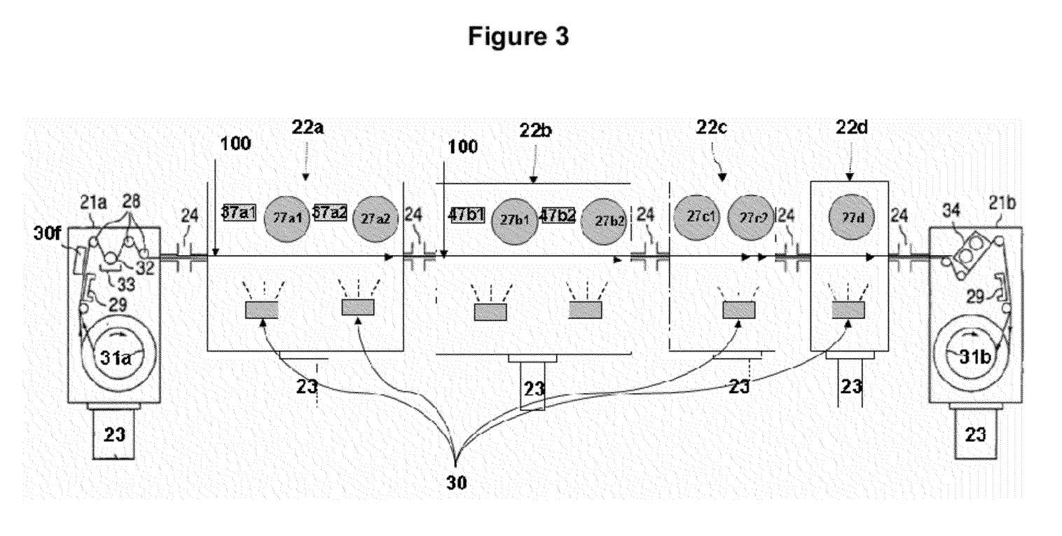

For example, a modular sputtering apparatus for making the solar cell, as illustrated in FIG. 3 (top view), may be used for depositing the layers. The apparatus is equipped with an input, or load, module 21a and a symmetrical output, or unload, module 21b. Between the input and output modules are process modules 22 (e.g., 22a, 22b, 22c and 22d, etc). The number of process modules 22 may be varied to match the requirements of the device that is being produced. Each module has a pumping device 23, such as vacuum pump, for example a high throughput turbomolecular pump, to provide the required vacuum and to handle the flow of process gases during the sputtering operation. Each module may have a number of pumps placed at other locations selected to provide optimum pumping of process gases. The modules are connected together at slit valves 24, which contain very narrow low conductance isolation slots to prevent process gases from mixing between modules. These slots may be separately pumped if required to increase the isolation even further. Other module connectors 24 may also be used. Alternatively, a single large chamber may be internally segregated to effectively provide the module regions, if desired. U.S. Published Application No. 2005/0109392 A1 (“Hollars”), filed on Oct. 25, 2004, discloses a vacuum sputtering apparatus having connected modules, and is incorporated herein by reference in its entirety.

The web substrate 100 is moved throughout the machine by rollers 28, or other devices. Additional guide rollers may be used. Rollers shown in FIG. 3 are schematic and non-limiting examples. Some rollers may be bowed to spread the web, some may move to provide web steering, some may provide web tension feedback to servo controllers, and others may be mere idlers to run the web in desired positions. The input spool 31a and optional output spool 31b thus are actively driven and controlled by feedback signals to keep the web in constant tension throughout the machine. In addition, the input and output modules may each contain a web splicing region or device 29 where the web 100 can be cut and spliced to a leader or trailer section to facilitate loading and unloading of the roll. In some embodiments, the web 100, instead of being rolled up onto output spool 31b, may be sliced into solar modules by the web splicing device 29 in the output module 21b. In these embodiments, the output spool 31b may be omitted. As a non-limiting example, some of the devices/steps may be omitted or replaced by any other suitable devices/steps. For example, bowed rollers and/or steering rollers may be omitted in some embodiments.

Heater arrays 30 are placed in locations where necessary to provide web heating depending upon process requirements. These heaters 30 may be a matrix of high temperature quartz lamps laid out across the width of the web. Infrared sensors provide a feedback signal to servo the lamp power and provide uniform heating across the web. In one embodiment, as shown in FIG. 3, the heaters are placed on one side of the web 100, and sputtering targets are placed on the other side of the web 100. Sputtering targets 27, 37 and 47 may be mounted on dual cylindrical rotary magnetron(s), or planar magnetron(s) sputtering sources, or RF sputtering sources.

After being pre-cleaned, the web substrate 100 may first pass by heater array 30f in module 21a, which provides at least enough heat to remove surface adsorbed water. Subsequently, the web can pass over roller 32, which can be a special roller configured as a cylindrical rotary magnetron. This allows the surface of electrically conducting (metallic) webs to be continuously cleaned by DC, AC, or RF sputtering as it passes around the roller/magnetron. The sputtered web material is caught on shield 33, which is periodically changed. Preferably, another roller/magnetron may be added (not shown) to clean the back surface of the web 100. Direct sputter cleaning of a web 100 will cause the same electrical bias to be present on the web throughout the machine, which, depending on the particular process involved, might be undesirable in other sections of the machine. The biasing can be avoided by sputter cleaning with linear ion guns instead of magnetrons, or the cleaning could be accomplished in a separate smaller machine prior to loading into this large roll coater. Also, a corona glow discharge treatment could be performed at this position without introducing an electrical bias.

Next, the web 100 passes into the process module 22a through valve 24. Following the direction of the imaginary arrows along the web 100, the full stack of layers may be deposited in one continuous process. The first transition metal layer 202 is then sputtered in the process module 22a over the web 100, as illustrated in FIG. 3 (and previously in FIG. 2A). Optionally, the process module 22a may include more than two pairs of targets, each pair of targets comprising a transition metal target 27a and an alkali-containing target 37a, arranged in such a way that the types of targets alternate and the series of targets end with a transition metal target 27a. The alkali-containing target 37a has a composition different from that of the transition metal target 27a.

The web 100 then passes into the process module 22b through valve 24. The second transition metal layer 203 may be sputtered in the process module 22b over the web 100. As illustrated in FIGS. 2B and 3, two pairs of targets are used for sputtering the second transition metal layer 203. Each pair of targets comprising a transition metal target 27b (e.g., molybdenum target) and a gallium-containing (e.g., gallium copper alloy) target 47b. The gallium containing target 47b has a composition different from that of the transition metal target 27b. Alternatively, the process module 22b may include only one target (e.g., a molybdenum gallium alloy target or a molybdenum copper gallium alloy target), one pair of transition metal targets 27b and a gallium-containing target 47b, or more than two pairs of transition metal target 27b and an gallium-containing target 47b.

The web 100 then passes into the next process module, 22c, for deposition of the at least one p-type semiconductor absorber layer 301. In a preferred embodiment shown in FIG. 3, the step of depositing the at least one p-type semiconductor absorber layer 301 includes reactively alternating current (AC) magnetron sputtering the semiconductor absorber layer from at least one pair of two conductive targets 27c1 and 27c2, in a sputtering atmosphere that comprises argon gas and a selenium-containing gas. In some embodiment, the pair of two conductive targets 27c1 and 27c2 comprise the same targets. For example, each of the at least two conductive targets 27c1 and 27c2 comprises copper, indium and gallium, or comprises copper, indium and aluminum. The selenium-containing gas may be hydrogen selenide or selenium vapor. In other embodiments, targets 27c1 and 27c2 may comprise different materials from each other. The radiation heaters 30 maintain the web at the required process temperature, for example, around 400-800° C., for example around 500-600° C., which is preferable for the CIS based alloy deposition.

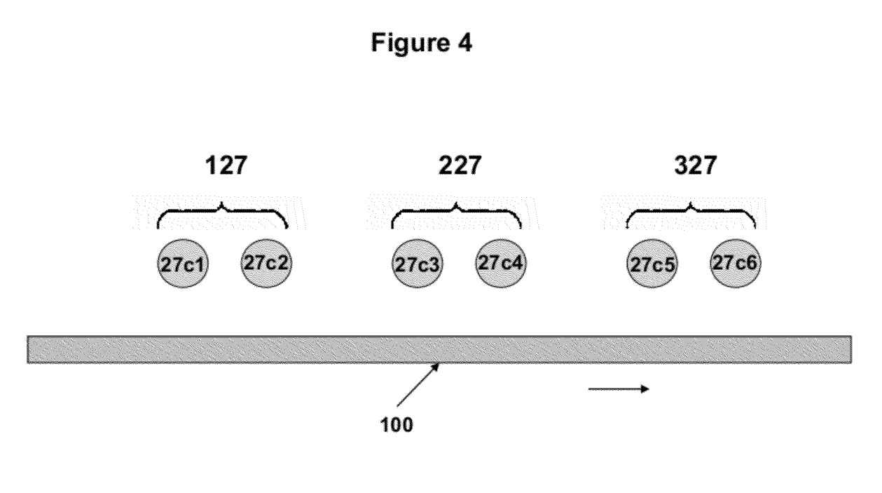

In some embodiments, at least one p-type semiconductor absorber layer 301 may comprise graded CIS based material. In this embodiment, the process module 22c further comprises at least two more pairs of targets (227, and 327), as illustrated in FIG. 4. The first magnetron pair 127 (27c1 and 27c2) are used to sputter a layer of copper indium diselenide while the next two pairs 227, 327 of magnetrons targets (27c3, 27c4 and 27c5, 27c6) sputter deposit layers with increasing amounts of gallium (or aluminum), thus increasing and grading the band gap. The total number of targets pairs may be varied, for example may be 2-10 pairs, such as 3-5 pairs. This will grade the band gap from about 1 eV at the bottom to about 1.3 eV near the top of the layer. Details of depositing the graded CIS material is described in the Hollars published application, which is incorporated herein by reference in its entirety.

Optionally, the alkali diffusion barrier layers 201 may be sputtered over the substrate 100 in a process module added between the process modules 21a and 22a. The second transition metal layer 203 may be sputtered over the first transition metal layer 202 in a process module added between the process modules 22a and 22b. Further, one or more process modules (not shown) may be added to deposit additional barrier layers and/or adhesion layer to the stack, if desired.

In some embodiments, one or more process modules (not shown) may be further added between the process modules 21a and 22a to sputter a back side protective layer over the back side of the substrate 100 before the first transition metal layer 202 is deposited on the front side of the substrate. U.S. application Ser. No. 12/379,428 (Attorney Docket No. 075122/0139) titled “Protective Layer for large-scale production of thin-film solar cells” and filed on Feb. 20, 2009, which is hereby incorporated by reference, describes such deposition process.

The web 100 may then pass into the process modules 22d and process modules (not shown) between 22d and 21b, for depositing the n-type semiconductor layer 302, and the transparent top electrode 400, respectively. Any suitable type of sputtering sources may be used, for example, rotating AC magnetrons, RF magnetrons, or planar magnetrons. Extra magnetron stations (not shown), or extra process modules (not shown) could be added for sputtering the optional one or more AR layers. Finally, the web 100 may be passed into output module 21b, where it is either wound onto the take up spool 31b, or sliced into solar cells using cutting apparatus 29.

It is to be understood that the present invention is not limited to the embodiment(s) and the example(s) described above and illustrated herein, but encompasses any and all variations falling within the scope of the appended claims. For example, as is apparent from the claims and specification, not all method steps need be performed in the exact order illustrated or claimed, but rather in any order that allows the proper formation of the solar cells of the present invention.

What is claimed is:

1. A solar cell, comprising:
a substrate;
a first transition metal layer located over the substrate, the first transition metal layer further comprising an alkali element or an alkali compound;
a second transition metal layer located over the first transition metal layer, the second transition metal layer further comprising gallium;
at least one p-type semiconductor absorber layer located over the second transition metal layer, wherein the p-type semiconductor absorber layer includes a copper indium selenide (CIS) based alloy material;
an n-type semiconductor layer located over the p-type semiconductor absorber layer; and
a top electrode located over the n-type semiconductor layer.

2. The solar cell of claim 1, wherein the p-type semiconductor absorber layer comprises copper indium gallium selenide containing alkali diffused from the first transition metal layer through the second transition metal layer.

3. The solar cell of claim 1, wherein the second transition metal layer further comprises at least one of copper, indium, aluminum, or combinations thereof.

4. The solar cell of claim 1, wherein:
the first transition metal layer comprises at least one Mo, W, Ta, V, Ti, Nb, or Zr;
the second transition metal layer comprises at least one of Mo, W, Ta, V, Ti, Nb, or Zr;
the alkali element or alkali compound is selected from the group consisting of Li, Na, or K.

5. The solar cell of claim 1, wherein the first transition metal layer further comprises a lattice distortion element or a lattice distortion compound.

6. The solar cell of claim 5, wherein the lattice distortion element or lattice distortion compound is selected from the group consisting of oxygen, MoO₂ and MoO₃.

7. The solar cell of claim 1, further comprising an alkali diffusion barrier layer located between the substrate and the first transition metal layer.

8. The solar cell of claim 7, wherein:
the alkali diffusion barrier layer comprises at least one of Mo, W, Ta, V, Ti, Nb, Zr, Cr, TiN, ZrN, TaN, VN, or combinations thereof; and
the alkali diffusion barrier layer has a thickness of 100 to 400 nm.

9. The solar cell of claim 7, further comprising an adhesion layer located between the substrate and the alkali diffusion barrier layer.

10. The solar cell of claim 1, wherein:
the first transition metal layer comprises molybdenum containing oxygen and sodium; and
the second transition metal layer comprises molybdenum containing gallium.

11. The solar cell of claim 1, wherein:
the first transition metal layer comprises molybdenum containing oxygen and sodium; and
the second transition metal layer comprises molybdenum containing gallium and copper.

12. The solar cell of claim 1, wherein:
the p-type semiconductor absorber layer comprises 0.03 to 1.5 atomic percent sodium diffused from the first transition metal layer;
the first transition metal layer comprises at least 59 atomic percent molybdenum, 5 to 40 atomic percent oxygen and 0.01 to 1.5 atomic percent sodium; and
the second transition metal layer comprises 50 to 90 atomic percent molybdenum, 10 to 50 atomic percent gallium and 0 to 10 atomic percent copper.

13. The solar cell of claim 1, wherein:
the first transition metal layer has a thickness of 100 to 500 nm; and
the second transition metal layer has a thickness of 20 to 80 nm.

14. A method of manufacturing a solar cell, comprising:
providing a substrate;
depositing a first transition metal layer over the substrate, the first transition metal layer further comprising an alkali element or an alkali compound;
depositing a second transition metal layer over the first transition metal layer, the second transition metal layer further comprising gallium;
depositing at least one p-type semiconductor absorber layer over the second transition metal layer, wherein the p-type semiconductor absorber layer includes a copper indium selenide (CIS) based alloy material;
depositing an n-type semiconductor layer over the p-type semiconductor absorber layer; and
depositing a top electrode over the n-type semiconductor layer;
wherein:
the second transition metal layer permits alkali diffusion from the first transition metal layer into the p-type semiconductor absorber layer during at least one of the steps of depositing the p-type semiconductor absorber layer, depositing the n-type semiconductor layer, or depositing the top electrode.

15. The method of claim 14, wherein the second transition metal layer further comprises at least one of copper, indium, aluminum, or combinations thereof.

16. The method of claim 14, wherein:
the at least one p-type semiconductor absorber layer comprises copper indium gallium selenide;
the first transition metal layer comprises at least one Mo, W, Ta, V, Ti, Nb, or Zr;
the second transition metal layer comprises at least one of Mo, W, Ta, V, Ti, Nb, or Zr; and
the alkali element or alkali compound is selected from the group consisting of Li, Na, or K.

17. The method of claim 14, wherein the first transition metal layer further comprises a lattice distortion element or a lattice distortion compound.

18. The method claim 17, wherein the lattice distortion element or lattice distortion compound is selected from the group consisting of oxygen, MoO₂ and MoO₃.

19. The method of claim 14, further comprising depositing an alkali diffusion barrier layer over the substrate prior to the step of depositing the first transition metal layer.

20. The method of claim 19, wherein the steps of depositing the alkali diffusion barrier layer, depositing the first transition metal layer and depositing the second transition metal layer comprise sputtering the alkali diffusion barrier layer, sputtering the first transition metal layer and sputtering the second transition metal layer in the same sputtering apparatus.

21. The method of claim 19, wherein:
the alkali element or alkali compound comprises sodium;
sodium diffuses from the first transition metal layer into the p-type semiconductor absorber layer through the second transition metal layer during the step of depositing the p-type semiconductor absorber layer; and
the alkali diffusion barrier layer substantially prevents sodium diffusion from the first transition metal layer into the substrate through the alkali diffusion barrier layer.

22. The method of claim 19, wherein:
the alkali diffusion barrier layer comprises at least one of Mo, W, Ta, V, Ti, Nb, Zr, Cr, TiN, ZrN, TaN, VN, or combinations thereof; and
the alkali diffusion barrier layer has a thickness of 100 to 400 nm.

23. The method of claim 19, further comprising depositing an adhesion layer over the substrate prior to the step of depositing the alkali diffusion layer.

24. The method of claim 14, wherein:
the p-type semiconductor absorber layer comprises copper indium gallium selenide containing 0.03 to 1.5 atomic percent sodium diffused from the first transition metal layer;
the first transition metal layer comprises at least 59 atomic percent molybdenum, 5 to 40 atomic percent oxygen and 0.01 to 1.5 atomic percent sodium; and
the second transition metal layer comprises 50 to 90 atomic percent molybdenum, 10 to 50 atomic percent gallium and 0 to 10 atomic percent copper.

25. The method of claim 14, wherein the step of depositing the second transition metal layer comprises sputtering the second transition metal layer from a target comprising a molybdenum copper gallium alloy or a molybdenum gallium alloy.

26. The method of claim 14, wherein:
the step of depositing the second transition metal layer comprises sputtering the second transition metal layer from a first target comprising molybdenum and a second target comprising gallium or a copper gallium alloy; and
the first and the second targets are located in the same vacuum chamber of a magnetron sputtering system.

27. A solar cell, comprising:
a substrate;
a first molybdenum layer located over the substrate, the first molybdenum layer further comprising sodium;
a second molybdenum layer located over the first molybdenum layer, the second molybdenum layer further comprising gallium;
a copper indium gallium selenide (CIGS) p-type semiconductor absorber layer located over the second molybdenum layer;
an n-type semiconductor layer located over the p-type semiconductor absorber layer; and
a top electrode located over the n-type semiconductor layer.

28. The solar cell of claim 27, wherein the p-type semiconductor absorber layer comprises copper indium gallium diselenide containing alkali diffused from the first molybdenum layer through the second molybdenum layer.

29. The solar cell of claim 27, wherein the second molybdenum layer further comprises at least one of copper, indium, aluminum, or combinations thereof.

30. The solar cell of claim 27, wherein the first molybdenum layer further comprises a lattice distortion element or a lattice distortion compound selected from the group consisting of oxygen, MoO₂ and MoO₃.

31. The solar cell of claim 27, further comprising:
an alkali diffusion barrier layer located between the substrate and the first molybdenum layer; and
an adhesion layer located between the substrate and the alkali diffusion barrier layer.

32. The solar cell of claim 31, wherein:
the p-type semiconductor absorber layer comprises copper deficient CIGS containing 0.03 to 1.5 atomic percent sodium diffused from the first molybdenum layer;
the adhesion layer comprises at least 90 atomic percent chromium;
the alkali diffusion barrier layer comprises at least 90 atomic percent molybdenum;
the first molybdenum layer comprises at least 59 atomic percent molybdenum, 5 to 40 atomic percent oxygen and 0.01 to 1.5 atomic percent sodium; and
the second molybdenum layer comprises 50 to 90 atomic percent molybdenum, 10 to 50 atomic percent gallium and 0 to 10 atomic percent copper.

33. The solar cell of claim 27, wherein:
the p-type semiconductor absorber layer is located directly on the second molybdenum layer; and
p-type semiconductor absorber layer comprises a first portion adjacent to the second molybdenum layer which contains more gallium then a second portion distant from the second molybdenum layer.
